(19) United States
(12) Patent Application Publication
(10) Pub. No.: US 2025/0231608 A1
(43) Pub. Date: Jul. 17, 2025

(54) DISPLAY DEVICE AND METHOD FOR OPERATING THE SAME

(71) Applicant: Samsung Electronics Co., Ltd., Suwon-si (KR)

(72) Inventors: Guehwan MA, Suwon-si (KR); Dahye KWON, Suwon-si (KR); Gwirang PARK, Suwon-si (KR)

(21) Appl. No.: 19/020,624

(22) Filed: Jan. 14, 2025

Related U.S. Application Data
(63) Continuation of application No. PCT/KR2024/021582, filed on Dec. 31, 2024.

(30) Foreign Application Priority Data
Jan. 11, 2024 (KR) 10-2024-0004949

(51) Int. Cl. G06F 1/3234; G09G 3/00; G09G 3/34

(52) U.S. Cl. CPC G06F 1/3265; G09G 3/006; G09G 3/3406; G09G 2330/021

(57) ABSTRACT

The disclosure relates to a device for monitoring power consumption in a display device and a method for operating the same. The display device may predict a first individual power consumption amount in a backlight unit based on a usage range of a driving current, a usage range of a driving voltage, and dimming driving data including a brightness control value and a pulse width (duty) for pulse width control for a display panel. The display device may predict a second individual power consumption amount corresponding to at least one module comprising circuitry configured to consume power in an operation mode based on a resolution and a per-time power consumption amount for each module. The display device may obtain a total power consumption amount by integrating the predicted first individual power consumption amount and the predicted second individual power consumption amount.

### CROSS-REFERENCE TO RELATED APPLICATIONS

This application is a continuation of International Application No. PCT/KR2024/021582 designating the United States, filed on Dec. 31, 2024, in the Korean Intellectual Property Receiving Office, and claiming priority to Korean Patent Application No. 10-2024-0004949, filed on Jan. 11, 2024, in the Korean Intellectual Property Office, the disclosures of each of which are incorporated by reference herein in their entireties.

### BACKGROUND

### Field

The disclosure relates to a display device for monitoring power consumption and a method for operating the same.

### Description of Related Art

Display devices may be classified into analog-type devices or digital-type devices depending on the type of source data for providing images. An advance in digital signal processing technology leads to rapid transition from analog to digital type.

The display device may be a device providing visual information using electrical signals. Efforts are being made to reduce energy consumption in the display device due to issues, such as environmental preservation. To achieve this, display devices should come up with hardware, such as a separate component or circuit to measure power consumption.

### SUMMARY

Embodiments of the disclosure may provide a display device and a method for operating the same, which predict power consumption and/or power consumption savings based on the operation state.

According to an example embodiment, a display device may comprise: communication circuitry configured to perform communication with an external electronic device based on at least one communication scheme, a speaker configured to output auditory information using an audio signal as an input, a display configured to output visual information using a video signal as an input, at least one memory, and at least one processor, comprising processing circuitry, operably connected to the communication circuitry, the speaker, the display, and/or the at least one memory. The memory may store instructions, wherein at least one processor, individually and/or collectively, is configured to execute the instructions and to cause the display device to: predict a first individual power consumption amount in a backlight unit including a backlight based on a usage range of a driving current, a usage range of a driving voltage, and dimming driving data including a brightness control value and a pulse width for pulse width control for a display panel, predict a second individual power consumption amount corresponding to at least one module including circuitry to consume power in an operation mode based on a resolution and a per-time power consumption amount for each module, and obtain a total power consumption amount by integrating the predicted first individual power consumption amount and the predicted second individual power consumption amount.

According to an example embodiment, a method for monitoring power consumption of a display device may comprise: predicting a first individual power consumption amount in a backlight unit comprising a backlight based on a usage range of a driving current, a usage range of a driving voltage, and dimming driving data including a brightness control value and a pulse width for pulse width control for a display panel, predicting a second individual power consumption amount corresponding to at least one module comprising circuitry to consume power in an operation mode based on a resolution and a per-time power consumption amount for each module, and obtaining a total power consumption amount by integrating the predicted first individual power consumption amount and the predicted second individual power consumption amount.

According to an example embodiment of the disclosure, one or more non-transitory computer-readable storage media stores one or more computer programs including computer-executable instructions that, when executed by one or more processors of an electronic device individually or collectively, cause the electronic device to perform operations. The operations comprising: predicting a first individual power consumption amount in a backlight unit comprising a backlight based on a usage range of a driving current, a usage range of a driving voltage, and dimming driving data including a brightness control value and a pulse width for pulse width control for a display panel; predicting a second individual power consumption amount corresponding to at least one module comprising circuitry configured to consume power in an operation mode based on a resolution and a per-time power consumption amount for each module; and obtaining a total power consumption amount by integrating the predicted first individual power consumption amount and the predicted second individual power consumption amount.

According to an example embodiment of the disclosure, a display device may save power consumption and monitor power consumption with a high level of accuracy even without separate hardware for measuring power consumption.

Effects of the disclosure are not limited to the foregoing, and other unmentioned effects will be apparent to one of ordinary skill in the art from the following description. In other words, unintended effects in practicing embodiments of the disclosure may also be derived by one of ordinary skill in the art from example embodiments of the disclosure.

### BRIEF DESCRIPTION OF THE DRAWINGS

The above and other aspects, features, and advantages of certain embodiments of the present disclosure will be more apparent from the following detailed description, taken in conjunction with the accompanying drawings, in which:

FIG. 1 is a block diagram illustrating an example configuration of a display device capable of operations described in the disclosure according to various embodiments;

FIG. 2 is a state transition diagram of a display device according to various embodiments;

FIG. 3 is a flowchart illustrating an example process performed to monitor power consumption in a display device according to various embodiments;

FIG. 4 is a flowchart illustrating an example process performed to monitor a power consumption saving in a display device according to various embodiments;

FIG. 5 is a timing diagram illustrating measuring a power consumption amount in a display device according to various embodiments; and

FIGS. 6A, 6B, 6C, and 6D are diagrams illustrating example user interfaces providing an energy consumption context of a display device in an electronic device according to various embodiments.

### DETAILED DESCRIPTION

Hereinafter, various example embodiments of the disclosure are described in greater detail with reference to the drawings. However, the disclosure may be implemented in other various forms and is not limited to the examples set forth herein. The same or similar reference denotations may be used to refer to the same or similar elements throughout the disclosure and the drawings. Further, for clarity and brevity, descriptions of well-known functions and configurations in the drawings and relevant descriptions may be omitted.

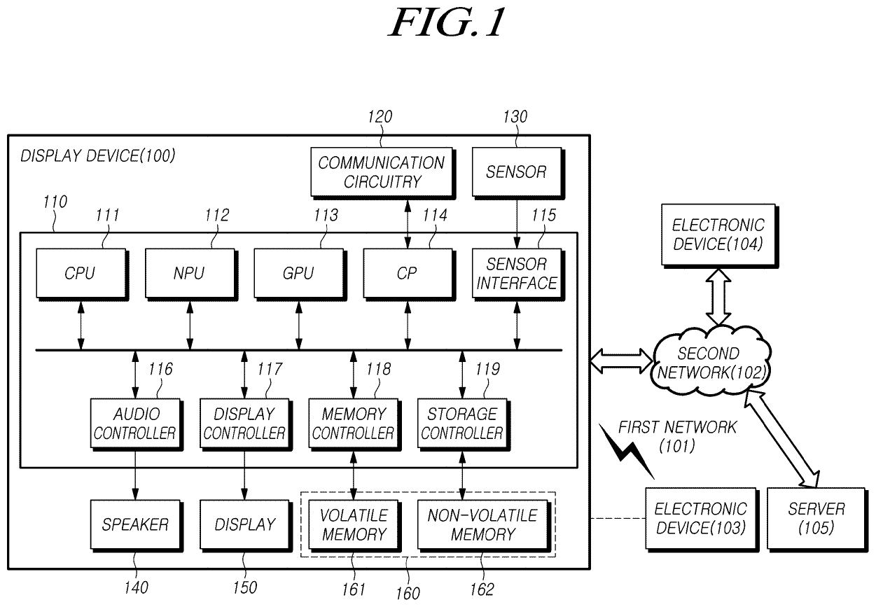

FIG. 1 is a block diagram illustrating an example configuration of a display device 100 capable of operations described herein according to various embodiments.

Referring to FIG. 1, a display device 100 may be one of various types of electronic devices, such as liquid crystal display (LCD), light emitting diode (LED), or organic light emitting diode (OLED) televisions (TVs), monitors, tablets, or other similar devices (not shown). The components illustrated in FIG. 1, and their relationships and functions are merely exemplary and do not limit implementations described or claimed in the disclosure.

The display device 100 may communicate with an external electronic device 103 (e.g., a smartphone) via the first network 101 (e.g., a short-range wireless communication network) in a network environment. The display device 100 may communicate with at least one of the external electronic device 104 (e.g., a smartphone) or the server 105 (e.g., a smart home server) via a second network 102 (e.g., a long-range wireless communication network) in the network environment. The display device 100 may communicate with an external electronic device (e.g., a refrigerator, a washing machine, a cleaner, an air conditioner, lighting, or the like) through the server 105. Each of the external electronic devices 103 or 104 may be the same as or different from the display device 100. All or some of the operations executed by the display device 100 may be executed by one or more of the external electronic devices 103, 104, or 105. For example, when the display device 100 should perform a function or service automatically or in response to a request from the user or another device, the display device 100 may request one or more external electronic devices to perform at least a part of the function or the service, instead of or in addition to executing the function or the service by itself. Upon receiving the request, the one or more external electronic devices may execute at least part of the requested function or service, or an additional function or service related to the request, and transfer a result of the execution to the display device 100. The display device 100 may process the result as it is or additionally, and may provide the same as at least part of the response to the request. To that end, cloud computing, distributed computing, mobile edge computing (MEC), or client-server computing technology may be used. The display device 100 may provide an ultra-low latency service using, e.g., distributed computing or mobile edge computing. The electronic device 104 may include an Internet of things (IoT) device. The server 105 may be an intelligent server using machine learning and/or a neural network. The electronic device 104 or the server 105 may be included in the second network 102. The display device 100 may be applied to intelligent services (e.g., smart home, smart city, smart car, or healthcare) based on 5G communication technology and IoT-related technology.

The display device 100 may include the processor (e.g., including processing circuitry) 110, the communication circuitry 120, the sensor 130, the speaker 140, the display 150, and/or the memory 160 (e.g., the volatile memory 161 and/or the non-volatile memory 162) as components. The components may be connected mutually or communicate signals (e.g., commands or data) therebetween based on a specified communication scheme (e.g., a bus, general purpose input and output (GPIO), serial peripheral interface (SPI), or mobile industry processor interface (MIPI)). The components are merely examples. For example, the display device 100 may include other components (e.g., a power management integrated circuit (PMIC), a connecting terminal, or an input/output interface). At least one of the components included in the display device 100 may be omitted, or one or more other components may be added. Some of the components included in the display device 100 may be integrated into one component.

The processor 110 may execute software (e.g., an application program, a driving program, and/or a system program) to control at least one other component (e.g., a hardware or software component) of the display device 100. To that end, the processor 110 may perform various data processing and/or operations. As at least part of the data processing and/or computation, the processor 110 may store a command or data received from another component (e.g., the communication circuitry 120 or the sensor 130) in the volatile memory 161. The processor 110 may process the command or data stored in the volatile memory 161, and may store resulting data in the non-volatile memory 162.

The processor 110 may be implemented as one or more integrated circuit (IC) chips and may perform various data processing. For example, the processor 110 (or an application processor (AP)) may be implemented as a system on chip (SoC) (e.g., one chip or chipset). The processor 110 may include sub components including a central processing unit (CPU) 111, a neural processing unit (NPU) 112, a graphics processing unit (GPU) 113, a communication processor (CP) 114, a sensor interface 115, an audio controller 116, a display controller 117, a memory controller 118, and/or a storage controller 119. The sub components are merely examples. For example, the processor 110 may further include other sub components (e.g., image signal processor (ISP)). For example, some sub components may be omitted in the processor 110. For example, some sub components may be included as separate components of the display device 100 outside the processor 110. For example, some sub components may be included in other components (e.g., the display 150). The processor 110 may include various processing circuitry and/or multiple processors. For example, as used herein, including the claims, the term “processor” may include various processing circuitry, including at least one processor, wherein one or more of at least one processor, individually and/or collectively in a distributed manner, may be configured to perform various functions described herein. As used herein, when “a processor”, “at least one processor”, and “one or more processors” are described as being configured to perform numerous functions, these terms cover situations, for example and without limitation, in which one processor performs some of recited functions and another processor(s) performs other of recited functions, and also situations in which a single processor may perform all recited functions. Additionally, the at least one processor may include a combination of processors performing various of the recited/disclosed functions, e.g., in a distributed manner. At least one processor may execute program instructions to achieve or perform various functions.

The CPU 111 (or the central processing circuit) may be configured to control sub components based on execution of instructions stored in the memory 160 (e.g., the volatile memory 161 and/or the non-volatile memory 162). The NPU 112 (or neural processing circuit) may be configured to execute operations (e.g., convolution computations) for an artificial intelligence model. The GPU 113 (or the graphics processing circuit) may be configured to execute parallel computations (e.g., rendering). The CP 114 (or communication processing circuit) may be configured to process data obtained from a sub component in the processor 110 into a format appropriate to be transmitted to another electronic device (e.g., the electronic device 103 or 104 or the server 105) through the communication circuitry 120 or process data obtained from the other electronic device (e.g., the electronic device 103 or 104) through the communication circuitry 120 into a format appropriate to be processed by the sub component. The sensor interface 115 (or a sensing data processing circuitry or a sensor hub) may be configured to process data about the state of the display device 100 and/or the state of the surroundings of the display device 100, which is obtained through the sensor 130, into a format suitable for a sub component in the processor 110. The audio controller 116 (or audio control circuitry) may be configured to cause the CPU 111 or the memory controller 118 to process an audio signal obtained from the memory 160 (e.g., volatile memory 161) into an audible signal appropriate to be output through the speaker 140. The display controller 118 (or the display control circuitry) may be configured to cause the CPU 111, the GPU 113 or the memory controller 118 to process an image obtained from the memory 160 (e.g., the volatile memory 161) into a format appropriate to be output by the display 150. The memory controller 118 (or the memory control circuitry) may be configured to control to read data from the volatile memory 161 and write the data to the volatile memory 161. The storage controller 119 (or the storage control circuitry) may be configured to control to read data from the non-volatile memory 162 and write the data to the non-volatile memory 162.

When the display device 100 includes a main processor (e.g., the CPU 111) and an auxiliary processor (e.g., the NPU 112, the GPU 113, the CP 114, the sensor interface 115, the audio controller 116, the display controller 117, the memory controller 118, and/or the storage controller 119), the auxiliary processor may be configured to use lower power than the main processor or to be specialized for a designated function, according to an operation mode (e.g., a power saving mode). The auxiliary processor may be implemented separately from, or as part of, the main processor.

The display device 100 may consume power corresponding to the operation mode. Hereinafter, the power consumed by the display device 100 may be referred to as ‘power consumption’. The operation mode may include, e.g., a normal mode, a low power mode (LPM), a background suspend mode, an always-on display mode (always on screen/ambient mode), a picture off mode, or a suspend mode. The normal mode may be an operation mode in which both video and audio may be output. The LPM may be an operation mode in which power consumption is minimized and/or reduced in a standby state. In the LPM, the display device 100 may use power consumption only enough to receive a signal from a remote controller. The background suspend mode may be an operation mode in which a preset image is displayed as a background screen through the display. The always-on display mode may be an operation mode in which a screen is continuously displayed through the display. The picture off mode may be an operation mode in which the output of the video is turned off and only the output of the audio is turned on. The picture off mode may be, e.g., a music listening mode. The suspend mode may be an operation mode in which all the operations by the display device 100 are temporarily suspended.

The power consumption of the display device 100 may be different for each operation mode. This is because the display device 100 may have different modules driven for each operation mode. In the normal mode, modules corresponding to a backlight unit (BLU), a cell of a panel, a mainboard, and a speaker may be driven. Accordingly, the processor 110 may integrate power consumption (hereinafter, referred to as “individual power consumption”) in each of the BLU, the cell, the main board, and the speaker to obtain power consumption (hereinafter, referred to as “total power consumption”) in the normal mode. In the LPM, a module corresponding to the main board may be driven. Accordingly, the processor 110 may obtain the individual power consumption as the main board operates at the low power as the total power consumption in the LPM. In the background suspend mode, the module corresponding to the main board may be driven. Accordingly, the processor 110 may obtain individual power consumption on the main board as total power consumption in the background suspend mode. In the always-on display mode, the modules corresponding to the BLU, the cell, and the main board may be driven. Accordingly, the processor 110 may obtain the total power consumption in the always-on display mode by integrating the individual power consumption in each of the BLU, the cell, and the main board. In the picture off mode, the modules corresponding to the main board and the speaker may be driven. Accordingly, the processor 110 may obtain the total power consumption in the picture off mode by integrating the individual power consumption in each of the main board and the speaker. In the suspend mode, none of the modules are driven. Accordingly, the processor 110 may determine the total power consumption in the suspend mode as “0”.

The processor 110 may obtain a power consumption amount (or an amount of energy consumption) by predicting or calculating individual power consumption for each module according to the operation mode of the display device 100. The processor 110 may obtain, e.g., the power consumption amount through calculation or prediction. The power consumption amount may refer to the amount of power WH consumed by at least one module for a predetermined time (e.g., 1 hour) due to the operation of the display device 100. The power consumption amount may include an individual power consumption amount or a total power consumption amount. The individual power consumption amount may be a power consumption amount calculated or predicted for each module according to the operation mode of the display device 100. The module may include at least one component that provides a defined function in the display device 100. The component may be one of the BLU, the cell, the main board, and the speaker. The module may include a unit implemented in hardware (H/W), software (S/W), or firmware. The module may be interchangeably used with terms such as logic, logic block, component, or circuit. The module may be an integrated component or a minimum unit, or part thereof, of the component, performing one or more functions. For example, the module may be implemented in the form of an application-specific integrated circuit (ASIC). The defined functions that may be provided by the module may include an operation for driving a backlight, an operation for outputting a video of a defined quality (e.g., resolution or average picture level (APL)), an operation for processing a video signal, or an operation for processing or outputting an audio signal. The module may include, e.g., a backlight driving module to perform the operation for driving the backlight. The module may include, e.g., a video output module to perform the operation of outputting a video of a defined quality (e.g., a resolution or an average picture level (APL)). The module may include, e.g., a video signal processing module to perform the operation for processing a video signal. The module may include, e.g., an audio signal processing/output module to perform the operation for processing or outputting an audio signal. As an example, the module may include one or more modules among the example described modules. The total power consumption amount may be obtained by integrating one or more individual power consumption amounts among the individual power consumption amounts.

The processor 110 may calculate or predict an individual power consumption amount for each detailed operation. For example, the processor 110 may calculate or predict a power consumption amount P_{BLU} (hereinafter, referred to as a “light source power consumption amount” or “first individual power consumption”) in a light source such as the backlight as the individual power consumption. For example, the processor 110 may calculate or predict the power consumption amount P_{CELL} depending on the quality of the output image (hereinafter, referred to as a “cell power consumption amount” or “second individual power consumption amount”) as the individual power consumption. For example, the processor 110 may calculate or predict a power consumption amount P_{MAIN} for processing an image signal in a specific circuit (e.g., the main board) (hereinafter, referred to as a “video processing power consumption amount” or “third individual power consumption amount”) as the individual power consumption amount. For example, the processor 110 may calculate or predict a power consumption amount P_{SPEAKER} for processing and outputting an audio signal (hereinafter, referred to as an “audio processing power consumption amount” or “fourth individual power consumption amount”) as the individual power consumption amount. The first to fourth individual power consumption amounts may be different for each operation mode of the display device 100.

When the processor 110 operates in the picture off mode, the power consumption amount (e.g., at least one of the first to fourth individual power consumption amounts) may be relatively reduced as compared with the normal mode. When the processor 110 operates in the LPM, the power consumption amount (e.g., at least one of the first to fourth individual power consumption amounts) may be relatively reduced as compared with the picture off mode.

The processor 110 may obtain the total power consumption amount for each operation mode. The total power consumption amount may vary depending on the operation mode of the display device 100. When the processor 110 operates in the picture off mode, the power consumption amount (e.g., the total power consumption amount) may be relatively reduced as compared with the normal mode. When the processor 110 operates in the LPM, the power consumption amount (e.g., the total power consumption amount) may be relatively reduced as compared to the picture off mode. The total power consumption amount corresponding to each of the operation modes may be obtained by integrating one or more detailed power consumption amounts calculated or predicted when the display device 100 operates in the corresponding operation mode.

The processor 110 may obtain a first power consumption amount in the LPM which is a power saving operation state. The first power consumption amount may be obtained in substantially same operation as the operation of obtaining the total power consumption amount, although the detailed items for predicting the individual power consumption amount may be different. The processor 110 may obtain the second power consumption amount in the normal operation state based on the first power consumption amount. The second power consumption amount may be obtained by reflecting illuminance sensor saving, motion analysis saving, or object analysis saving based on at least one of pulse width modulation (PWM), ANA, dimming block, or current index depending on the dimming scheme for controlling driving of the display 150 to the first power consumption amount. The dimming scheme may include a local dimming scheme or a pulse width modulation (PWM) dimming scheme. In the local dimming scheme, a contrast ratio and/or power consumption may be enhanced by dividing the screen into a plurality of areas in the display device 100, and lowering the brightness of the area corresponding to the dark portion of an image, or increasing the brightness of the area corresponding to the bright portion of the image. The PWM dimming scheme may increase or decrease the screen brightness (e.g., luminance) of the display device 100 by controlling the pulse width.

The illuminance sensor saving, the motion analysis saving, or the object analysis saving may be targets in which power is saved in the LPM which is a power saving operation state. The processor 110 may determine a power consumption amount corresponding to a difference between the first power consumption amount and the second power consumption amount as a power saving amount.

The processor 110 may calculate the instantaneous power consumption amount with respect to the total power consumption amount obtained corresponding to the operation mode. The instantaneous power consumption amount may be a power consumption amount predicted every integration period (e.g., 10 seconds) for measuring power consumption. For example, the instantaneous power consumption amount may be calculated by ‘total power consumption amount*integration period/3600’.

The communication circuitry 120 may support establishing a direct (e.g., wired) communication channel or a wireless communication channel between the display device 100 and the external electronic device (e.g., the electronic device 103 or 104, or the server 105) and performing communication via the established communication channel. The communication circuitry 120 may support direct (e.g., wired) communication or wireless communication in response to control of the CP 114. The communication circuitry 120 may include a wireless communication module (e.g., a cellular communication module, a short-range wireless communication module, or a global navigation satellite system (GNSS) communication module) or a wired communication module (e.g., a local area network (LAN) communication module or a power line communication module). A corresponding one of these communication modules may communicate with the external electronic device 104 via a first network 101 (e.g., a short-range communication network, such as Bluetooth™, wireless-fidelity (Wi-Fi) direct, or infrared data association (IrDA)) or a second network 102 (e.g., a long-range communication network, such as a legacy cellular network, a 5G network, a next-generation communication network, the Internet, or a computer network (e.g., local area network (LAN) or wide area network (WAN)). These various types of communication modules may be implemented as a single component (e.g., a single chip), or may be implemented as multi components (e.g., multi chips) separate from each other.

The sensor 130 may detect an operational state (e.g., power or temperature) of the display device 100 or an environmental state (e.g., the user's state) external to the display device 100, and generate an electrical signal or data value corresponding to the detected state. The sensor 130 may include, e.g., a gesture sensor, a gyro sensor, an atmospheric pressure sensor, a magnetic sensor, an acceleration sensor, a grip sensor, a proximity sensor, a color sensor, an infrared (IR) sensor, a bio sensor, a temperature sensor, a humidity sensor, or an illuminance sensor.

The speaker 140 may output sound signals to the outside of the display device 100. The speaker 140 may be used for general purposes such as multimedia playback or recording playback. The volume of the speaker 140 may increase or decrease in response to control of the audio controller 116. The speaker 140 may vary in power consumption depending on the volume of sound output. For example, power consumption by the speaker 140 may increase as the volume increases and may decrease as the volume becomes lower.

The display 150 may visually provide information to the outside (e.g., the user) of the display device 100. The display 150 may include, for example, a display, a hologram device, or a projector and control circuitry for controlling the corresponding device. The display 150 may include a touch sensor configured to sense a touch, or a pressure sensor configured to measure the intensity of the force generated by the touch.

The memory 160 may store various data used by at least one component (e.g., the processor 110 or the sensor 130) of the display device 100. The data may include, for example, software (e.g., the program) and/or input data or output data for a command related thereto. The memory 160 may include the volatile memory 161 or the non-volatile memory 162.

The display device 100 may further include an interface or connecting terminal. The interface may support one or more specified protocols to be used for the display device 100 to be connected with the external electronic device (e.g., the electronic device 103) directly (e.g., wiredly) or wirelessly. The interface may include, e.g., a high definition multimedia interface (HDMI), a universal serial bus (USB) interface, a secure digital (SD) card interface, or an audio interface. A connecting terminal may include a connector via which the display device 100 may be physically connected with the external electronic device (e.g., the electronic device 103). The connecting terminal may include, for example, an HDMI connector, a USB connector, an SD card connector, or an audio connector (e.g., a headphone connector).

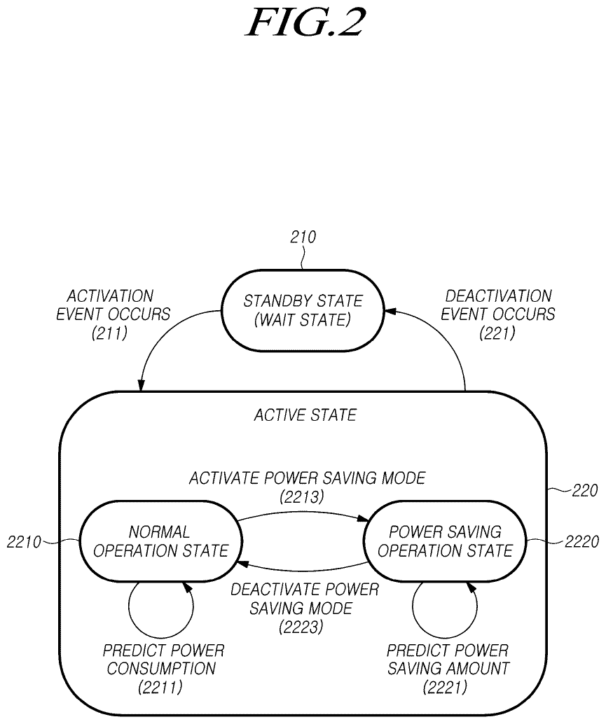

FIG. 2 is a state transition diagram of a display device (e.g., the display device 100 of FIG. 1) according to various embodiments.

Referring to FIG. 2, the display device 100 may include a standby state (e.g., WAIT STATE) 210 or an active state 220 as the operation state. The display device 100 may operate in two modes in the standby state 210. For example, the display device 100 may operate in one of a sleep state (SLEEP STATE) or an idle state (IDLE STATE) based on whether the state transition from the standby state 210 to the active state 220 is easy. The display device 100 may operate in two modes in the active state 220. For example, in the active state 220, the display device 100 may operate in one of the normal operation state 2210 or the power saving operation state 2220 based on whether power consumption is saved. The power saving operation state 2220 may be a state of operating with relatively low power consumption as compared to the normal operation state 2210. Accordingly, the display device 100 may save the power consumption amount in the power saving operation state 2220 as compared to the normal operation state 2210.

When an activation event occurs (operation 211) in the standby state 210, the display device 100 may transition to the active state 220. The activation event may correspond to a screen output request generated by the display device 100. The display device 100 may transition from the standby state 210 to the normal operation state 2210 which is the active state 220. When a deactivation event occurs (operation 221) in the active state 220, the display device 100 may transition to the standby state 210. The deactivation event may occur when no other event occurs for a predetermined time after the screen output by the display device 100 is terminated. The display device 100 may transition from the power saving operation state 2220, which is the active state 220, to the standby state 210.

The display device 100 may consume power when operating in the normal operation state 2210. The display device 100 may obtain the power consumption amount (or energy consumption amount) by monitoring the power consumption (operation 2211). The display device 100 may obtain, e.g., the power consumption amount through calculation or prediction. The power consumption amount may be a power consumption amount for a predetermined time due to the operation of the display device 100. The power consumption amount may include an individual power consumption amount or a total power consumption amount. The individual power consumption amount may be calculated or predicted power consumption amount for each detailed operation of the display device 100. The detailed operation may include an operation for driving a backlight, an operation for obtaining an output image of a defined quality (e.g., resolution or APL), an operation for processing a video signal, or an operation for processing an audio signal. The total power consumption amount may be obtained by integrating one or more individual power consumption amounts among the individual power consumption amounts.

The display device 100 may calculate or predict an individual power consumption amount for each detailed operation. The display device 100 may calculate or predict, e.g., the light source power consumption amount as the individual power consumption amount. The display device 100 may calculate or predict, e.g., the cell power consumption amount as the individual power consumption amount. The display device 100 may calculate or predict, e.g., the video processing power consumption amount as the individual power consumption amount. The display device 100 may calculate or predict, e.g., the audio processing power consumption amount as the individual power consumption amount. Each of the individual power consumption amounts may be different for each operation mode of the display device 100. The operation mode of the display device 100 may include, e.g., a normal mode, a picture off mode, or an LPM. When the display device 100 operates in the picture off mode, the power consumption amount (e.g., at least one of the individual power consumption amounts) may be relatively reduced as compared with the normal mode. When the display device 100 operates in the LPM, the power consumption amount (e.g., at least one of the individual power consumption amounts) may be relatively reduced as compared to the picture off mode.

The display device 100 may obtain the total power consumption amount for each operation mode. The total power consumption amount may vary depending on the operation mode of the display device 100. When the display device 100 operates in the picture off mode, the total power consumption amount may be relatively reduced as compared with the normal mode. When the display device 100 operates in the LPM, the total power consumption amount may be relatively reduced as compared to the picture off mode. The total power consumption amount corresponding to each of the operation modes may be obtained by integrating one or more calculated or predicted detailed power consumption amounts when the display device 100 operates in a corresponding operation mode.

When the power saving mode is activated (operation 2213) in the normal operation state 2210, the display device 100 may transition to the power saving operation state 2220. When transitioning to the power saving operation state 2220, the display device 100 may obtain the first power consumption amount. The first power consumption amount may be obtained in substantially same operation as the operation of obtaining the total power consumption amount, although the detailed items for predicting the individual power consumption amount may be different. The processor 110 may obtain the second power consumption amount in the normal operation state based on the first power consumption amount. The second power consumption amount may be obtained by reflecting illuminance sensor saving, motion analysis saving, or object analysis saving based on at least one of PWM, ANA, dimming block, or current index according to the dimming scheme for controlling driving of the display 150 to the first power consumption amount. The illuminance sensor saving, the motion analysis saving, or the object analysis saving may be targets in which power is saved in the LPM which is a power saving operation state. The processor 110 may determine a power consumption amount corresponding to a difference between the first power consumption amount and the second power consumption amount as a power saving amount (operation 2221). When the power saving mode is deactivated (operation 2223) in the power saving operation state 2220, the display device 100 may transition to the normal operation state 2210.

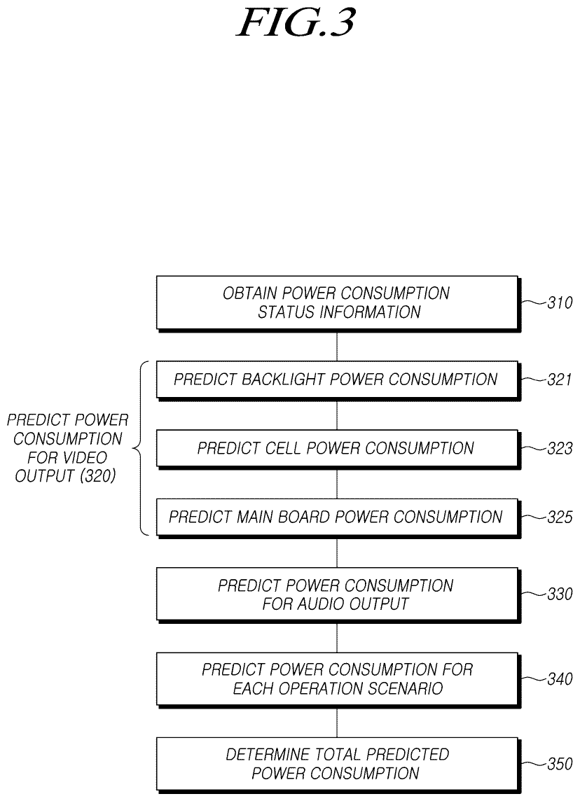

FIG. 3 is a flowchart illustrating an example process performed to monitor power consumption in a display device (e.g., the display device 100 of FIG. 1) according to various embodiments.

Referring to FIG. 3, in operation 310, the display device 100 may obtain power consumption status information. The display device 100 may pre-determine a driving current specification based on a driving current curve according to a physical property type of a panel used in a display (e.g., the display 150 of FIG. 1). The driving current specification may define a usage range (e.g., CD1_min (2.01 A) to CD1_max (16.80 A)) of the driving current. The display device 100 may pre-determine the driving voltage specification based on the driving voltage curve according to the physical property type of the panel used in the display 150. The driving voltage specification may define a usage range (e.g., Vf_min (51.34V) to Vf_max (58.17V)) of the driving voltage. The display device 100 may obtain a pulse width (duty) for PWM, a brightness control value (ANA), a dimming block, or a current index for controlling power consumption based on the dimming scheme. The brightness control value may be a control value for controlling the brightness of the BLU. The control value may adjust the driving current and/or the driving voltage supplied to the BLU.

Table 1 below illustrates an example of power consumption status information.

TABLE 1

| Items | Example |
|---|---|
| Product name | Q9AAA |
| SW model name | Q9BBB |
| Panel type | 85CCCC |
| driving current specification (Iₘᵢₙ/Iₘₐₓ) | 2.02/16.80 |
| driving voltage specification (Vₘᵢₙ/Vₘₐₓ) | 51.34/58.17 |
| Block count | 2340 |
| P_{CELL}(WH) | 23.60 |
| P_{MAIN} (WH) | 75.00 |
| P_{MAIN}_{_{—}}_{LPM}(WH) | 12.00 |
| P_{SPEAKER} (WH) | 22.00 |
| Surplus power consumption amount (alpha) | 0 |

In Table 1, power consumption status information is defined corresponding to one product to which one SW model is applied, but power consumption status information may be defined for a combination of a plurality of SW models, a plurality of products, and/or a plurality of panel types.

In Table 1, the driving current specification is based on the curve of the driving current, and defines the driving current minimum value Iₘᵢₙ and the driving current maximum value Iₘₐₓ. The display device 100 may adjust a driving current for driving the BLU between the driving current minimum value Iₘᵢₙ and the driving current maximum value Iₘₐₓ. In Table 1, the driving voltage specification is based on the curve of the driving voltage, and defines the driving voltage minimum value Vₘᵢₙ and the driving voltage maximum value Vₘₐₓ. The display device 100 may adjust a driving voltage for driving the BLU between the driving voltage minimum value Vₘᵢₙ and the driving voltage maximum value Vₘₐₓ. The curve of the driving current and/or the curve of the driving voltage may be defined by physical properties (panel type) of the panel.

Table 1 defines the individual power consumption amount P_{CELL} in the cell per hour, the individual power consumption amount P_{MAIN} in the main board per hour in the normal mode, the individual power consumption amount P_{MAIN_LPM} in the main board per hour in the LPM, or the individual power consumption amount P_{SPEAKER} in the speaker per hour.

The surplus power consumption amount (alpha) in Table 1 above defines the amount of power that may be unnecessarily consumed in addition to the amount of power that the main board substantially consumes in the cell.

The display device 100 may obtain the operation mode being applied among the normal mode, the picture off mode, or the LPM. The display device 100 may obtain the resolution or the APL for determining the quality of the output image by analyzing the output image. The display device 100 may obtain information about the usage scenario of power consumption. The display device 100 may obtain information about the volume output through the speaker (e.g., the speaker 140 of FIG. 1).

In operation 320, 330, or 340, the display device 100 may calculate or predict the individual power consumption amount for each detailed operation. The detailed operations may include an operation for driving a backlight, an operation for obtaining an output image of a defined quality (e.g., resolution or APL), an operation for processing a video signal, or an operation for processing an audio signal. The individual power consumption may include, e.g., a light source power consumption amount, a cell power consumption amount, a video processing power consumption amount, or an audio processing power consumption amount.

In operation 320, the display device 100 may predict power consumption for outputting a video. This may correspond to predicting the power consumption amount consumed to output an image through the display 150. The predicting of the power consumption for outputting a video may include an operation of predicting backlight power consumption, an operation of predicting cell power consumption, or an operation of predicting main board power consumption.

Table 2 below illustrates an example of detailed items that may be considered to predict individual power consumption amounts for each operation mode and module.

TABLE 2

| | | | | |
|---|---|---|---|---|
| Operation mode | dimming | cell | main board | speaker |
| normal mode | PWM | resolution | resolution | volume |
| picture off mode | brightness | APL | Operation | N/A |
| | control | | mode | |
| | value | | | |
| LPM | dimming block | N/A | N/A | N/A |
| background | current index | N/A | N/A | N/A |
| suspend | | | | |
| mode | | | | |

According to Table 2, the operation mode of the display device 100 may include a normal mode, a picture off mode, and an LPM. Detailed items that may be considered to predict the individual power consumption amount in the BLU in the display device 100 may include at least one of PWM, brightness control value, dimming block, or current index. The PWM, the brightness control value, the dimming block, or the current index included in the detailed items may be defined for each dimming type. Detailed items that may be considered to predict the individual power consumption amount in the cell in the display device 100 may include resolution or APL. The resolution or APL included in the detailed items may be defined according to the quality of the video to be output. Detailed items that may be considered to predict the individual power consumption amount in the main board in the display device 100 may include resolution or operation mode. Detailed items that may be considered to predict the individual power consumption amount in the speaker in the display device 100 may include volume. The volume may be determined between a minimum volume value and a maximum volume value.

In operation 321, the display device 100 may predict backlight power consumption. This may correspond to predicting the light source power consumption amount used in the operation for driving the backlight. For example, the display device 100 may predict the light source power consumption amount based on the brightness control value and the pulse width according to the PWM. The backlight power consumption may include power consumed by applying the dimming scheme. Power consumed by applying the dimming scheme may be affected by the pulse width of the PWM, ANA, dimming block, or current index. For example, the display device 100 may calculate dimming driving data such as the driving current curve, the driving voltage curve, the ANA, and the pulse width of the PWM in units of a defined voltage V_{sync} to infer the current and/or the voltage level actually applied to the display 150, and calculate or predict power consumption based thereon.

For example, the display device 100 may predict the current consumption Irms and the voltage consumption V based on the driving current specification Iₘᵢₙ/Iₘₐₓ and the driving voltage specification Vₘᵢₙ/Vₘₐₓ according to the current curve and voltage curve corresponding to the dimming type in Table 1. The display device 100 may predict the light source power consumption amount P using the predicted current consumption Irms and the voltage consumption V. The display device 100 may further consider the brightness control value ANA and the duty for PWM to obtain the current consumption Irms and the voltage consumption V.

Equation 1 below illustrates an example of obtaining the current value Irms for controlling the BLU.

$$Irms = I \times \frac{DutySum}{1023} / 1000 \qquad [ Equation 1 ]$$

Here, I may be defined as

$$I = ( {I}_{max} - {I}_{min} ) \times \frac{A N A}{1023} + {I}_{min} .$$

In Equation 1 above, Iₘᵢₙ and Iₘₐₓ may be obtained from the power consumption status information defined in Table 1 above. In Equation 1, the brightness control value ANA is a control value used for brightness of the BLU and may be a value already known. In Equation 1, DutySum may be an average value of the duty for controlling all cells on the entire screen.

Equation 2 below illustrates an example of obtaining the voltage value V for controlling the BLU.

$$V = ( {V}_{max} - {V}_{min} ) \times \frac{A N A}{1023} \times \frac{DutySum}{1023} + {V}_{min} + alpha \qquad [ Equation 2 ]$$

In Equation 2, Vₘᵢₙ, Vₘₐₓ, and alpha may be obtained from the power consumption status information defined in Table 1. In Equation 2, the brightness control value ANA is a control value used for brightness of the BLU and may be a value already known. In Equation 2, DutySum may be an average value of the duty for controlling all cells on the entire screen.

Equation 3 below illustrates an example of obtaining the individual power consumption amount consumed in the BLU.

$$P = Irms \times V \times BLOCK \times 1.05 \qquad [ Equation 3 ]$$

Here, BLOCK may be the number of blocks defined in Table 1 above.

Equations 1 to 3 described above may be defined differently according to the dimming type. For example, a constant (e.g., 1023 in Equation 1) that may vary depending on the number of pixels may be changed (e.g., 4095) depending on the dimming type.

In operation 323, the display device 100 may predict cell power consumption. The cell power consumption amount may be a power consumption amount used in an operation for obtaining an output image of defined quality. The display device 100 may predict the cell power consumption considering the APL value and/or the resolution. The display device 100 may obtain the APL value and/or the resolution by analyzing image information about the image being output through the display 150.

For example, when the resolution of the image to be output is UHD or higher, the display device 100 may obtain the cell power consumption amount by multiplying P_{CELL}, which is the power consumption amount per hour defined corresponding to the cell in Table 1, by a weight (e.g., 1.1) according to the high resolution.

For example, when the resolution of the image to be output is equal to or lower than FHD, the display device 100 may obtain P_{CELL}, which is the power consumption amount per hour defined corresponding to the cell in Table 1, as the cell power consumption amount.

In operation 325, the display device 100 may predict the main board power consumption. The main board power consumption may be the video processing power consumption amount used in an operation for processing a video signal. The display device 100 may predict the video processing power consumption considering the resolution and/or the operation mode. The display device 100 may obtain the resolution and/or the operation mode by analyzing image information about the image being output through the display 150. Since the driving block of the main board of the display device 100 may be determined according to the operation mode, the main board power consumption amount may be different due to the operation mode.

For example, when the resolution of the image to be output is UHD or higher, the display device 100 may obtain the main board power consumption amount by multiplying the P_{MAIN}, which is the power consumption amount per hour defined corresponding to the main board in Table 1, by a weight (e.g., 1.1) according to the high resolution.

For example, when the resolution of the image to be output is equal to or lower than FHD, the display device 100 may obtain P_{MAIN}, which is the power consumption amount per hour defined corresponding to the main board in Table 1, as the main board power consumption amount.

For example, when the operation mode is LPM, the display device 100 may obtain the main board power consumption amount from P_{MAIN_LPM}, which is the power consumption amount per hour defined corresponding to the main board in Table 1.

For example, when the operation mode is the picture off mode, the display device 100 may obtain the main board power consumption amount by multiplying P_{MAIN}, which is the power consumption amount per hour defined corresponding to the main board in Table 1, by a weight (e.g., 0.7) according to the picture off mode which is the operation mode.

For example, when the operation mode is the background suspend mode, the display device 100 may obtain the main board power consumption amount by multiplying P_{MAIN}, which is the power consumption amount per hour defined corresponding to the main board in Table 1, by a weight (e.g., 0.6) according to the background suspend mode which is the operation mode.

In operation 330, the display device 100 may predict audio processing power consumption for audio output. The audio processing power consumption amount may be the power consumption amount used for the operation for processing an audio signal. The display device 100 may predict the audio processing power consumption amount based on the output volume of the speaker 140.

For example, when the volume level set by the user is set to SET_{VOLUME}, the display device 100 may obtain the speaker power consumption amount P_{SPEAKER}^{(SET_VOLUME/100)-1} by reflecting the set volume level SET_{VOLUME} to P_{SPEAKER}, which is the power consumption amount per hour defined corresponding to the speaker in Table 1.

In operation 340, the display device 100 may predict power consumption for each operation scenario. For each operation scenario, total power consumption or instantaneous power consumption may be calculated or predicted by comprehensively considering the image being output, backlight control information, and the operation mode. In operation 340, the display device 100 may obtain the total power consumption amount or the instantaneous power consumption amount corresponding to the operation mode by integrating the light source power consumption amount, the cell power consumption amount, the video processing power consumption amount, or the audio processing power consumption amount predicted for each operation scenario.

In operation 350, the display device 100 may determine the total predicted power consumption. The total power consumption amount may be obtained by integrating one or more individual power consumption amounts among the individual power consumption amounts.

Table 3 below illustrates an example in which the processor 110 predicts or calculates the total power consumption in each operation mode.

TABLE 3

| | |
|---|---|
| Operation mode | Total power consumption (WH) |
| normal mode | P_{BLU} + P_{CELL} + |
| | P_{MAIN} + P_{SPEAKER} |
| LPM | P_{MAIN}_{_{—}}_{LPM} |
| background suspend mode | P_{MAIN} |
| always-on display mode | P_{BLU} + P_{CELL} + P_{MAIN} |
| (always on screen/ambient mode) | |
| picture off mode | P_{MAIN} + P_{SPEAKER} |
| suspend mode | 0 |
| when AI saving mode is off | P_{AI}_{_{—}}_{OFF}_{_{—}}_{BLU} + P_{CELL} + |
| | P_{MAIN} + P_{SPEAKER} |

According to Table 3, since both video and audio should be output in the normal mode, the total power consumption may be obtained by summing the individual power consumption amounts P_{BLU}, P_{CELL}, and P_{MAIN} in the BLU, the cell, and the main board, respectively, which are modules related to video output, and the individual power consumption amount P_{SPEAKER} in the speaker, which is a module related to audio output.

According to Table 3 above, in the LPM, the individual power consumption amount P_{MAIN_LPM} in the main board which is enough to be able to receive a remote control signal without outputting video and audio may be obtained as the total power consumption amount.

According to Table 3, since a still image needs to be output in the background suspend mode, the individual power consumption amount P_{MAIN} in the main board may be obtained as the total power consumption amount.

According to Table 3, since video needs to be output in the always-on display, the total power consumption amount may be obtained by summing the individual power consumption amounts P_{BLU}, P_{CELL}, and P_{MAIN} in the BLU, the cell, and the main board, respectively, which are modules related to video output.

According to Table 3, since only audio should be output with video output cut off in the picture off mode, the total power consumption amount may be obtained by the sum of the individual power consumption amounts P_{MAIN} and P_{SPEAKER} in the main board and the speaker, respectively, which are modules related to audio output.

According to Table 3, since no module operates in the suspend mode, the individual power consumption amounts and the total power consumption amount may be 0.

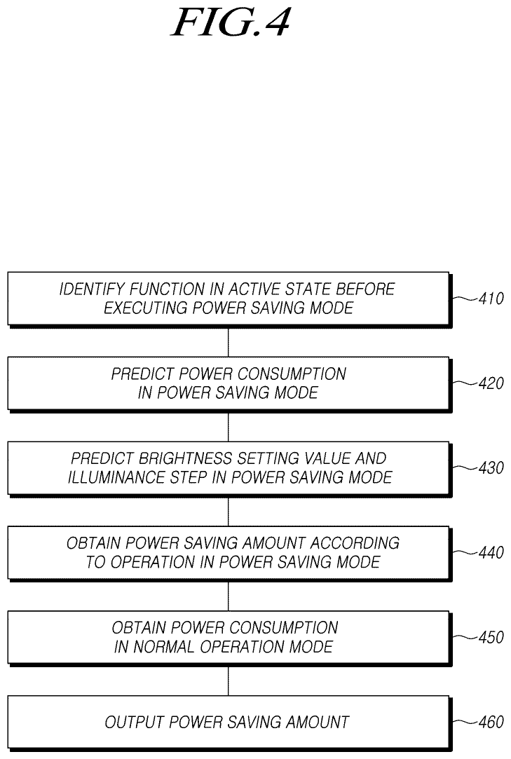

FIG. 4 is a flowchart illustrating an example process performed to monitor a power consumption saving in a display device (e.g., the display device 100 of FIG. 1) according to various embodiments.

Referring to FIG. 4, in operation 410, the display device 100 may identify a function that is in an active state before the power saving mode (e.g., the power saving operation state 2220 of FIG. 2) is executed. For example, the display device 100 may determine whether an illuminance sensor, a content motion analysis function, or a content region-of-interest (ROI) analysis function is activated in the normal operation state (e.g., the normal operation state 2210 of FIG. 2). This may be considered to select a target for saving power consumption in the power saving operation state 2220.

In operation 420, the display device 100 may predict power consumption in the power saving mode. An operation in which the display device 100 predicts an individual power consumption amount for each module and obtains a total power consumption amount based thereon has been described above. The display device 100 may predict power consumption by the same operation even in the power saving mode. According to an embodiment, power consumed by the display device 100 may be different depending on the dimming scheme for illuminance adjustment. In the display device 100, a dimming scheme of flashing a light source such as a backlight based on image characteristics may be applied. The dimming scheme may include a local dimming scheme or a pulse width modulation (PWM) dimming scheme. In the local dimming scheme, a contrast ratio and/or power consumption may be enhanced by dividing the screen into a plurality of areas in the display device 100, lowering the brightness of the area corresponding to the dark portion of an image, or increasing the brightness of the area corresponding to the bright portion of the image. The PWM dimming scheme may increase or decrease the screen brightness (e.g., luminance) of the display device 100 by controlling the pulse width.

In operation 430, the display device 100 may predict a brightness setting value and an illuminance step in the power saving mode (e.g., the power saving operation state 2220 of FIG. 2). The brightness setting value predicted in the power saving mode may have a relatively low value as compared with the normal operation state 2210. The illuminance step predicted in the power saving mode may have a relatively lower step as compared with the normal operation state 2210. When the illuminance level is low, an image of low illuminance may be output by the display device 100. As the brightness setting value decreases, the power consumption amount used for this may be reduced. As the illuminance level decreases, the power consumption amount used for this may be reduced. The decrease in the power consumption amount may indicate an increase in the power saving.

In operation 440, the display device 100 may obtain (e.g., determine) power consumption predicted to be saved in the power saving mode. For example, the display device 100 may calculate or predict the power consumption amount to be additionally used in a state in which the power saving mode is activated, based on the dimming power consumption, the brightness setting value, or the illuminance step. For example, in order to predict dimming power consumption, the display device 100 may predict a saving amount that may be obtained by reducing power consumption in an illuminance sensor. In order to predict dimming power consumption, the display device 100 may predict a saving amount that may be obtained by reducing power consumed in motion analysis. In order to predict dimming power consumption, the display device 100 may predict a saving amount that may be obtained by reducing power consumed in object analysis. The display device 100 may obtain a saving amount for dimming power consumption by totaling the predicted saving amount for each of the three items.

In operation 450, the display device 100 may obtain power consumption in the normal operation mode 2210. For example, the display device 100 may obtain the power consumption in the normal operation mode 2210 by applying the power saving amount to the power consumption amount in the power saving mode.

In operation 460, the display device 100 may output the power saving amount. For example, the display device 100 may provide information about the power saving amount to the user terminal such as a smartphone.

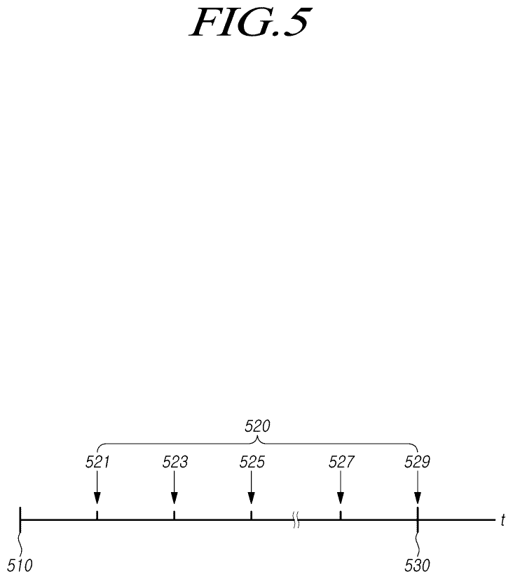

FIG. 5 is a timing diagram for measuring a power consumption amount in a display device (e.g., the display device 100 of FIG. 1) according to various embodiments.

Referring to FIG. 5, the display device 100 may start monitoring power consumption at a predetermined start time 510. The predetermined time may be, e.g., a time at which the operation state of the display device 100 transitions from the standby state (e.g., the standby state 210 of FIG. 2) to the active state (e.g., the active state 220 of FIG. 2). The active state may include a normal operation state (e.g., the normal operation state 2210 of FIG. 2) or a power saving operation state (e.g., the power saving operation state 2220 of FIG. 2).

The display device 100 may predict the power consumption amount at defined periods 520, including periods 521, 523, 525, 527, and 529. The display device 100 may predict the power consumption amount in response to the occurrence of a defined event. The defined event may include, e.g., an event in which the user requests the current power consumption amount. The defined event may include, e.g., an event in which the operation mode or the service of the display device 100 is changed. The operation mode may include the standby state 210 or the active state 220. The active state may include the normal operation state 2210 or the power saving operation state 2220. The service change may be, e.g., a change in the type of content provided by the display device 100. For example, when the user requests playback of the music content while watching the video content through the display device 100, the display device 100 may recognize that the service has been changed. The display device 100 may consider that a defined event has occurred only for a change in a service in which a change in the power consumption amount is predicted.

The display device 100 may predict the individual power consumption amount corresponding to each of detailed operations that generate power consumption in the operation mode every period 521, 523, 525, 527, and 529. The operation mode may be one of the normal mode, the picture off mode, or the LPM. The detailed operations may include an operation for driving a backlight, an operation for obtaining an output image of defined quality, an operation for processing a video signal, or an operation for processing an audio signal. The individual power consumption may include, e.g., a light source power consumption amount, a cell power consumption amount, a video processing power consumption amount, or an audio processing power consumption amount. The light source power consumption amount may be a power consumption amount used in an operation for driving the backlight. The light source power consumption may be predicted based on the ANA or the pulse width according to the PWM. The cell power consumption amount may be a power consumption amount used in an operation for obtaining an output image of defined quality. The cell power consumption may be predicted considering the APL value and/or the resolution. The APL value and/or the resolution may be obtained by analyzing image information about the image being output through a display (e.g., the display 150 of FIG. 1) of the display device 100. The video processing power consumption amount may be the power consumption amount used for the operation for processing a video signal. The video processing power consumption may be predicted considering the resolution and/or use scenario. The audio processing power consumption amount may be the power consumption amount used for the operation for processing an audio signal. The audio processing power consumption may be predicted based on the output volume of the speaker 140.

To predict the individual power consumption amount, the display device 100 may consider a driving current specification defining a usage range of a preset driving current and a driving voltage specification defining a usage range of a preset driving voltage. The driving current specification may be predetermined based on the driving current curve according to the physical property type of the panel used in the display 150 of the display device 100. The driving voltage specification may be predetermined based on the driving voltage curve according to the physical property type of the panel used in the display 150 of the display device 100.

The display device 100 may calculate an average of individual power consumption amounts predicted for each defined period 521, 523, 525, 527, and 529 corresponding to the detailed operation, and determine the average individual power consumption amount as the individual power consumption amount of the corresponding detailed operation.

The display device 100 may obtain the total power consumption amount in the corresponding operation mode by integrating the individual power consumption amount predicted for each detailed operation at a predetermined end point 530. When integrating the individual power consumption, the display device 100 may apply a different gain for each detailed operation. For example, the gain to be applied to the individual power consumption amount may be applied based on an error range that may occur in predicting the corresponding individual power consumption amount. In other words, the corresponding gain may be used to correct an error.

The display device 100 may obtain a first power consumption amount in a power saving operation state 2220. The first power consumption amount may be obtained in substantially same operation as the operation of obtaining the total power consumption amount, although the detailed item for predicting the individual power consumption amount may be different. The display device 100 may obtain the second power consumption amount in the normal operation state 2210 based on the first power consumption amount. The second power consumption amount may be obtained by reflecting illuminance sensor saving, motion analysis saving, or object analysis saving based on at least one of PWM, ANA, dimming block, or current index according to the dimming scheme for controlling driving of the display 150 to the first power consumption amount. The illuminance sensor saving, the motion analysis saving, or the object analysis saving may be targets in which power is saved in the power saving operation state 2220.

The display device 100 may determine a power consumption amount corresponding to a difference between the first power consumption amount and the second power consumption amount as a power saving amount.

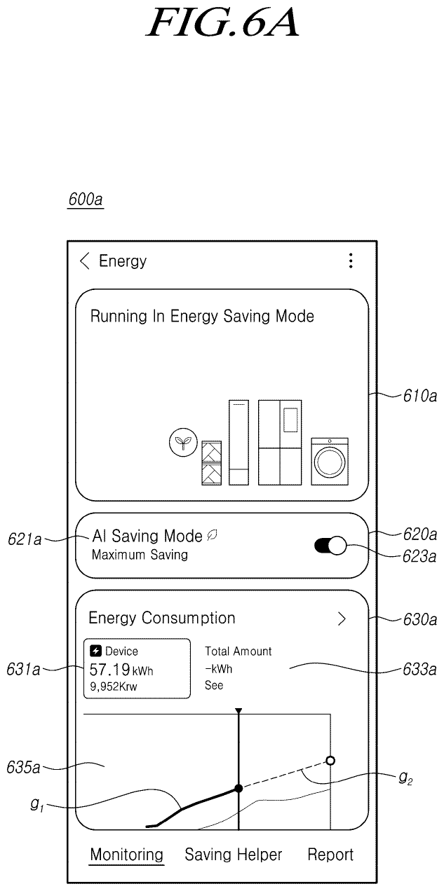

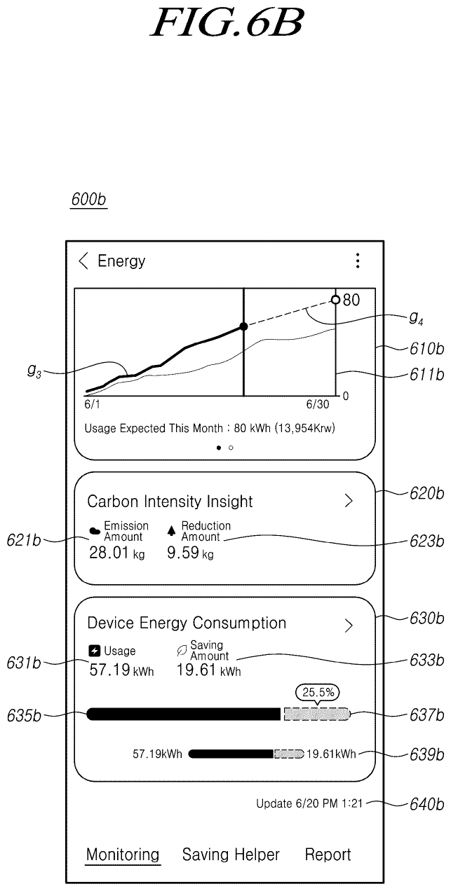

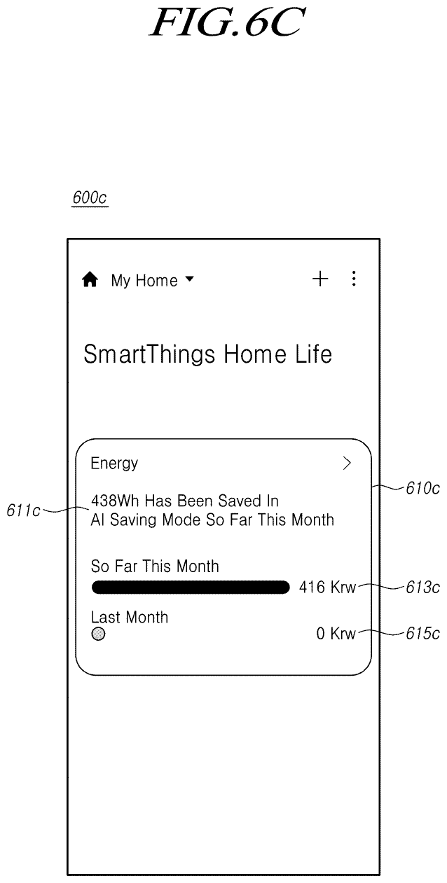

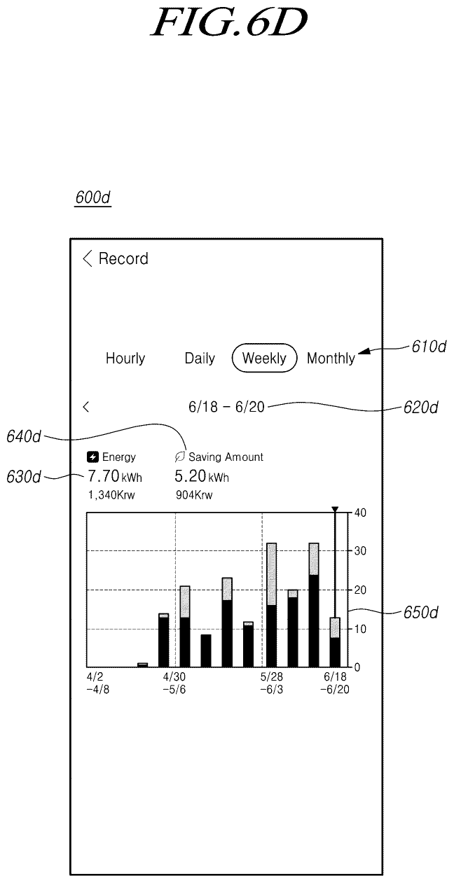

FIGS. 6A, 6B, 6C, and 6D are diagrams illustrating example user interfaces for providing an energy consumption context of a display device (e.g., the display device 100 of FIG. 1) in an electronic device (e.g., the electronic device 103 or 104 of FIG. 1) according to various embodiments. The electronic device 103 or 104 may be an electronic product such as a smartphone, a tablet, or a laptop computer having a defined application program installed to be capable of providing management such as operation or control of a smart home.

Referring to FIG. 6A, when a defined application program is executed at the request of the user, the electronic device 103 or 104 may output a screen 600a including information related to energy (e.g., power) use of the display device 100 as visual information. For example, the electronic device 103 or 104 may display identifiers of home appliances running in the energy saving mode and/or a notification message (e.g., running in energy saving mode) indicating the same in a defined display area 610a.

The electronic device 103 or 104 may output a display window 620a through a defined display area through which the user may control whether to activate the AI saving mode. The display window 620a may include an indication 621a (e.g., “AI saving mode”) for indicating the target to be selected for whether to activate or not, and/or an operation unit 623a for selecting activation or deactivation by the user's operation (e.g., dragging) therearound.

The electronic device 103 or 104 may output information for indicating energy consumption to the user through a display window 630a. Information output through the display window 630a may include the energy consumption amount (e.g., 57.19 kWh) used by a specific device (e.g., the display device 100) or a payment cost (e.g., KRW 9,952) for energy consumption (631a). The information output through the display window 630a may include the total energy consumption amount 633a used in the home. The information output through the display window 630a may include a graph 635a indicating a change g₁ in energy consumption amount used by the display device 100 from a start time of a period (e.g., every month) to monitor the energy consumption amount to the current time and a change g₂ in energy consumption predicted thereafter.

Referring to FIG. 6B, when a defined application program is executed at the request of the user, the electronic device 103 or 104 may output a screen 600b including information related to energy (e.g., power) use of the display device 100 as visual information.

The electronic device 103 or 104 may output information for indicating energy consumption to the user through a display window 610b. The information output through the display window 610b may include a graph 611b indicating a change g₃ in energy consumption amount used by the display device 100 from a start time of a period (e.g., every month) to monitor the energy consumption amount to the current time and a change g₄ in energy consumption predicted thereafter. Information for indicating the energy consumption may include the energy consumption amount (e.g., 80 kWh) expected to be used this month by a specific device (e.g., the display device 100) or a payment cost (e.g., KRW 13,954) for energy consumption amount.

The electronic device 103 or 104 may output, through the display window 620b, information related to a carbon intensity insight due to energy consumption expected to be used this month by the display device 100. The information related to the carbon intensity insight may include a carbon emission amount (e.g., 28.01 kg) 621b and/or a reduction amount (e.g., 9.59 kg) 623b.

The electronic device 103 or 104 may output, through the display window 630b, information about energy consumption expected to be used this month by the display device 100. The information about the energy consumption amount may include energy consumption amount (e.g., 57.19 kWh) 631b and/or saving amount (e.g., 19.61 kWh) 633b. The information about the energy consumption amount may include a graph indicating, among the total energy consumption amount predicted to be used by the display device 100 in the period (e.g., every month) for monitoring the energy consumption amount, the energy consumption amount (e.g., 57.19 kWh) 635b used from the start time of the period to the current time (e.g., 1:21 p.m., June 20 640b) and the energy consumption amount 637b predicted to be used later. The graph may represent a ratio of the energy consumption amount 635b already used and the energy consumption amount 637b to be used in the future. The graph 639b may numerically represent the energy consumption amount (e.g., 57.19 kWh) already used and the energy consumption amount (e.g., 19.61 kWh) to be used in the future.

Referring to FIG. 6C, when the user requests information about the energy (e.g., power) consumption amount of this month in an application program for controlling a smart home, the electronic device 103 or 104 may output the energy consumption amount of this month, which has been used so far, as visual information through a screen 600c. For example, the electronic device 103 or 104 may output, through the display window 610c of the screen 600c, a notification message 611c saying, “438 Wh has been saved in AI saving mode so far this month.” The display window 610c may display information (e.g., KRW 416) 613c about the energy consumption amount used from the start time in the period (e.g., every month) to monitor energy consumption amount to the current time. The display window 610c may also display information 615c regarding the amount of energy consumed last month.

Referring to FIG. 6D, when a defined application program is executed at the request of the user, the electronic device 103 or 104 may output a screen 600d for identifying energy consumption amount on the display 150.

For example, the screen 600d may include an identifier 610d (e.g., an emoticon or an icon) for selecting a period (or duration) for identifying energy consumption amount. The identifier 610d may include, e.g., an identifier for selecting each of hourly, daily, weekly, or monthly as the period for identifying energy consumption amount. In FIG. 6D, “weekly” is selected as the period for identifying energy consumption amount. A deadline (e.g., June 18 to June 20) 620d corresponding to the weekly period may be displayed on the screen 600d.

For example, the screen 600d may include energy consumption amount (e.g., 7.70 kWh) 630d and/or saving amount (e.g., 5.20 kWh) 640d. The energy consumption amount (e.g., 7.70 kWh or KRW 1,340) 630d and/or the saving amount (e.g., 5.20 kWh or KRW 904) 640d may be displayed for a period (e.g., June 18 to June 20) 620d for indicating the energy consumption amount.

For example, the screen 600d may include a graph 650d for indicating a weekly energy consumption amount selected as a period (or duration) for identifying energy consumption amount. The graph 650d provides energy consumption amount and saving amount on a weekly basis in the form of a bar.

According to an example embodiment, a display device may comprise: communication circuitry configured to perform communication with an external electronic device based on at least one communication; a speaker configured to output auditory information using an audio signal as an input; a display configured to output visual information using a video signal as an input; at least one memory; at least one processor, comprising processing circuitry, operably connected to the communication circuitry, the speaker, the display, and/or the at least one memory. At least one processor, individually and/or collectively, may be configured to execute the instructions, and cause the display device to perform at least one operation comprising: predicting a first individual power consumption amount in a backlight unit comprising a backlight based on a usage range of a driving current, a usage range of a driving voltage, and dimming driving data including a brightness control value and a pulse width for pulse width control for a display panel; predicting (a second individual power consumption amount corresponding to at least one module comprising circuitry configured to consume power in an operation mode based on a resolution and a per-time power consumption amount for each module; and obtaining a total power consumption amount by integrating the predicted first individual power consumption amount and the predicted second individual power consumption amount.

According to an example embodiment, the operation mode may be one of a normal mode, a picture off mode, or a low power mode (LPM).

According to an example embodiment, the usage range of the driving current may be determined based on a driving current curve according to a physical property type of the display panel.

According to an example embodiment, the usage range of the driving voltage may be determined based on a driving voltage curve according to the physical property type of the display panel.

According to an example embodiment, the at least one module may include at least one of a module comprising circuitry configured to perform an operation for driving a backlight, a module comprising circuitry configured to perform an operation for obtaining an output image of defined quality, a module comprising circuitry configured to perform an operation for processing a video signal, or a module comprising circuitry configured to perform an operation for processing an audio signal.

According to an example embodiment, the at least one operation may include, in the operation of obtaining the output image of a defined quality, predicting cell power consumption considering an average picture level (APL) value and/or a resolution.

According to an example embodiment, the at least one operation may include, in the operation of processing the video signal, predicting video processing power consumption based on the resolution and/or the operation mode.

According to an example embodiment, the at least one operation may include, in the operation for processing the audio signal, predicting audio processing power consumption based on an output volume of the speaker.

According to an example embodiment, the at least one operation may include obtaining the resolution or the APL value by analyzing image information about an image being output through the display.

According to an example embodiment, the at least one operation may include obtaining the power consumption amount in a power saving operation state.

According to an example embodiment, the at least one operation may include, in the power saving operation state, obtaining a power saving amount based on an illuminance sensor saving, a motion analysis saving, or an object analysis saving, based on at least one of the PWM, the brightness control value, a dimming block, or a current index according to a dimming scheme for controlling driving of the display.

According to an example embodiment, the at least one operation may include predicting the power consumption amount in a normal operation state based on the obtained power saving amount and the obtained power consumption amount.

According to an example embodiment, the at least one operation may include outputting the obtained power consumption amount and the obtained power saving amount through the display.

According to an example embodiment, the at least one operation may include controlling the communication circuitry to transfer information about the obtained total power consumption amount, the obtained power consumption amount, or the obtained power saving amount to an external electronic device.

According to an example embodiment, a display device may provide a power consumption monitoring method. The method may comprise: predicting a first individual power consumption amount in a backlight unit comprising a backlight based on a usage range of a driving current, a usage range of a driving voltage, and dimming driving data including a brightness control value and a pulse width for pulse width control for a display; predicting a second individual power consumption amount corresponding to at least one module comprising circuitry configured to consume power in an operation mode based on a resolution and a per-time power consumption amount for each module; and obtaining a total power consumption amount by integrating the predicted first individual power consumption amount and the predicted second individual power consumption amount.

According to an example embodiment, the operation mode may be one of a normal mode, a picture off mode, or a low power mode (LPM).

According to an example embodiment, the usage range of the driving current may be determined based on a driving current curve according to a physical property type of the display panel.

According to an example embodiment, the usage range of the driving voltage may be determined based on a driving voltage curve according to the physical property type of the display panel.

According to an example embodiment, the method may comprise allowing at least one of an operation for driving a backlight, an operation for obtaining an output image of defined quality, an operation for processing a video signal, or an operation for processing an audio signal to be performed by the at least one module.

According to an example embodiment, the method may comprise, in the operation of obtaining the output image of defined quality, predicting cell power consumption considering an average picture level (APL) value and/or a resolution.

According to an example embodiment, the method may comprise, in the operation of processing the video signal, predicting video processing power consumption based on the resolution and/or the operation mode.

According to an example embodiment, the method may comprise, in the operation for processing the audio signal, predicting audio processing power consumption based on an output volume of the speaker.

According to an example embodiment, the method may comprise obtaining the resolution or the APL value by analyzing image information about an image being output through the display.

According to an example embodiment, the method may comprise obtaining the power consumption amount in a power saving operation state.

According to an example embodiment, the method may comprise, in the power saving operation state, obtaining a power saving amount based on an illuminance sensor saving, a motion analysis saving, or an object analysis saving, based on at least one of the PWM, the brightness control value, a dimming block, or a current index according to a dimming scheme for controlling driving of the display.

According to an example embodiment, the method may comprise predicting the power consumption amount in a normal operation state based on the obtained power saving amount and the obtained power consumption amount.

According to an example embodiment, the method may comprise outputting the obtained power consumption amount and the obtained power saving amount through the display.

According to an example embodiment, the method may comprise transferring information about the obtained total power consumption amount, the obtained power consumption amount, or the obtained power saving amount to an external electronic device.

According to an example embodiment, a program for executing a method of switching an activation function in the display device 100 described above may be recorded in a non-transitory computer-readable storage medium.

The display device 100 according to various embodiments of the disclosure may be one of various types of electronic devices. The electronic devices may include, for example, a portable communication device (e.g., a smartphone), a computer device, a portable multimedia device, a portable medical device, a camera, a wearable device, a home appliance, or the like. According to an embodiment of the disclosure, the electronic devices are not limited to those described above.

It should be appreciated that various embodiments of the disclosure and the terms used therein are not intended to limit the technological features set forth herein to particular embodiments and include various changes, equivalents, or replacements for a corresponding embodiment. With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), the element may be coupled with the other element directly (e.g., wiredly), wirelessly, or via a third element.

As used herein, the term “module” may include a unit implemented in hardware, software, or firmware, or any combination thereof, and may interchangeably be used with other terms, for example, “logic,” “logic block,” “part,” or “circuitry”. A module may be a single integral component, or a minimum unit or part thereof, adapted to perform one or more functions. For example, according to an embodiment, the module may be implemented in a form of an application-specific integrated circuit (ASIC).

Various embodiments as set forth herein may be implemented as software (e.g., the program) including one or more instructions that are stored in a storage medium (e.g., the memory 160) that is readable by a machine (e.g., the display device 100). For example, a processor (e.g., the processor 110) of the machine (e.g., the display device 100) may invoke at least one of the one or more instructions stored in the storage medium, and execute it, with or without using one or more other components under the control of the processor. This allows the machine to be operated to perform at least one function according to the at least one instruction invoked. The one or more instructions may include a code generated by a compiler or a code executable by an interpreter. The storage medium readable by the machine may be provided in the form of a non-transitory storage medium. Wherein, the “non-transitory” storage medium is a tangible device, and may not include a signal (e.g., an electromagnetic wave), but this term does not differentiate between where data is semi-permanently stored in the storage medium and where the data is temporarily stored in the storage medium.

According to an embodiment, a method according to various embodiments of the disclosure may be included and provided in a computer program product. The computer program products may be traded as commodities between sellers and buyers. The computer program product may be distributed in the form of a machine-readable storage medium (e.g., compact disc read only memory (CD-ROM)), or be distributed (e.g., downloaded or uploaded) online via an application store (e.g., Play Store™), or between two user devices (e.g., smart phones) directly. If distributed online, at least part of the computer program product may be temporarily generated or at least temporarily stored in the machine-readable storage medium, such as memory of the manufacturer's server, a server of the application store, or a relay server.

According to various embodiments, each component (e.g., a module or a program) of the above-described components may include a single entity or multiple entities. Some of the plurality of entities may be separately disposed in different components. According to various embodiments, one or more of the above-described components may be omitted, or one or more other components may be added. Alternatively or additionally, a plurality of components (e.g., modules or programs) may be integrated into a single component. In such a case, according to various embodiments, the integrated component may still perform one or more functions of each of the plurality of components in the same or similar manner as they are performed by a corresponding one of the plurality of components before the integration. According to various embodiments, operations performed by the module, the program, or another component may be carried out sequentially, in parallel, repeatedly, or heuristically, or one or more of the operations may be executed in a different order or omitted, or one or more other operations may be added.

While the disclosure has been illustrated and described with reference to various example embodiments, it will be understood that the various example embodiments are intended to be illustrative, not limiting. It will be further understood by those skilled in the art that various changes in form and detail may be made without departing from the true spirit and full scope of the disclosure, including the appended claims and their equivalents. It will also be understood that any of the embodiment(s) described herein may be used in conjunction with any other embodiment(s) described herein.

What is claimed is:

1. A display device, comprising:
communication circuitry configured to perform communication with an external electronic device based on at least one communication scheme;
a speaker configured to output auditory information using an audio signal as an input;
a display configured to output visual information using a video signal as an input;
at least one memory; and
at least one processor, comprising processing circuitry, operably connected to the communication circuitry, the speaker, the display, and/or the at least one memory, wherein the memory stores instructions, wherein at least one processor, individually and/or collectively, is configured to execute the instructions and to:
predict a first individual power consumption amount in a backlight unit comprising a backlight based on a usage range of a driving current, a usage range of a driving voltage, and dimming driving data including a brightness control value and a pulse width for pulse width control for a display panel;
predict a second individual power consumption amount corresponding to at least one module comprising circuitry configured to consume power in an operation mode based on a resolution and a per-time power consumption amount for each module; and
obtain a total power consumption amount by integrating the predicted first individual power consumption amount and the predicted second individual power consumption amount.

2. The display device of claim 1, wherein the usage range of the driving current is determined based on a driving current curve according to a physical property type of the display panel, and
wherein the usage range of the driving voltage is determined based on a driving voltage curve according to the physical property type of the display panel.

3. The display device of claim 1, wherein the at least one module includes at least one of a module comprising circuitry configured to perform an operation for driving a backlight, a module comprising circuitry configured to perform an operation for obtaining an output image of a defined quality, a module comprising circuitry configured to perform an operation for processing a video signal, or a module comprising circuitry configured to perform an operation for processing an audio signal, and
wherein the operation mode includes one of a normal mode, a picture off mode, or a low power mode (LPM).

4. The display device of claim 3, wherein at least one processor, individually and/or collectively, is configured to:
in the operation of obtaining the output image of the defined quality, predict cell power consumption based on an average picture level (APL) value and/or a resolution;
in the operation of processing the video signal, predict video processing power consumption based on the resolution and/or the operation mode;
in the operation for processing the audio signal, predict audio processing power consumption based on an output volume of the speaker; and
obtain the resolution or the APL value by analyzing image information about an image being output through the display.

5. The display device of claim 4, wherein at least one processor, individually and/or collectively, is configured to:
obtain the power consumption amount in a power saving operation state; and
in the power saving operation state, obtain a power saving amount based on an illuminance sensor saving, a motion analysis saving, or an object analysis saving, based on at least one of the PWM, the brightness control value, a dimming block, or a current index according to a dimming scheme for controlling driving of the display.

6. The display device of claim 5, wherein at least one processor, individually and/or collectively, is configured to predict the power consumption amount in a normal operation state based on the obtained power saving amount and the obtained power consumption amount.

7. The display device of claim 5, wherein at least one processor, individually and/or collectively, is configured to control the display device to output the obtained power consumption amount and the obtained power saving amount through the display.

8. The display device of claim 5, wherein at least one processor, individually and/or collectively, is configured to control the communication circuitry to transfer information about the obtained total power consumption amount, the obtained power consumption amount, or the obtained power saving amount to an external electronic device.

9. A method for monitoring power consumption of a display device, the method comprising:
predicting a first individual power consumption amount in a backlight unit comprising a backlight based on a usage range of a driving current, a usage range of a driving voltage, and dimming driving data including a brightness control value and a pulse width for pulse width control for a display panel;
predicting a second individual power consumption amount corresponding to at least one module comprising circuitry configured to consume power in an operation mode based on a resolution and a per-time power consumption amount for each module; and
obtaining a total power consumption amount by integrating the predicted first individual power consumption amount and the predicted second individual power consumption amount.

10. The method of claim 9, wherein the usage range of the driving current is determined based on a driving current curve according to a physical property type of the display panel, and
wherein the usage range of the driving voltage is determined based on a driving voltage curve according to the physical property type of the display panel.

11. The method of claim 9, further comprising allowing at least one of an operation for driving a backlight, an operation for obtaining an output image of a defined quality, an operation for processing a video signal, or an operation for processing an audio signal to be performed by the at least one module,
wherein the operation mode is one of a normal mode, a picture off mode, or a low power mode (LPM).

12. The method of claim 11, wherein predicting the individual power consumption amount includes:
in the operation of obtaining the output image of the defined quality, predicting cell power consumption based on an average picture level (APL) value and/or a resolution;
in the operation of processing the video signal, predicting video processing power consumption based on the resolution and/or the operation mode;
in the operation for processing the audio signal, predicting audio processing power consumption based on an output volume of the speaker; and
obtaining the resolution or the APL value by analyzing image information about an image being output through the display.

13. The method of claim 12, further comprising:
obtaining the power consumption amount in a power saving operation state; and
in the power saving operation state, obtaining a power saving amount based on an illuminance sensor saving, a motion analysis saving, or an object analysis saving, based on at least one of the PWM, the brightness control value, a dimming block, or a current index according to a dimming scheme for controlling driving of the display.

14. The method of claim 13, wherein obtaining the power saving amount includes predicting the power consumption amount in a normal operation state based on the obtained power saving amount and the obtained power consumption amount.

15. The method of claim 13, further comprising:
outputting the obtained power consumption amount and the obtained power saving amount through the display; and
transferring information about the obtained total power consumption amount, the obtained power consumption amount, or the obtained power saving amount to an external electronic device.

16. One or more non-transitory computer-readable storage media storing one or more computer programs including computer-executable instructions that, when executed by one or more processors of an electronic device individually or collectively, cause the electronic device to perform operations, the operations comprising:
predicting a first individual power consumption amount in a backlight unit comprising a backlight based on a usage range of a driving current, a usage range of a driving voltage, and dimming driving data including a brightness control value and a pulse width for pulse width control for a display panel;
predicting a second individual power consumption amount corresponding to at least one module comprising circuitry configured to consume power in an operation mode based on a resolution and a per-time power consumption amount for each module; and
obtaining a total power consumption amount by integrating the predicted first individual power consumption amount and the predicted second individual power consumption amount.

17. The one or more non-transitory computer-readable storage media of claim 16, wherein the usage range of the driving current is determined based on a driving current curve according to a physical property type of the display panel, and
wherein the usage range of the driving voltage is determined based on a driving voltage curve according to the physical property type of the display panel.

18. The one or more non-transitory computer-readable storage media of claim 16, the operations further comprising:
allowing at least one of an operation for driving a backlight, an operation for obtaining an output image of a defined quality, an operation for processing a video signal, or an operation for processing an audio signal to be performed by the at least one module,
wherein the operation mode is one of a normal mode, a picture off mode, or a low power mode (LPM).

19. The one or more non-transitory computer-readable storage media of claim 18, wherein predicting the individual power consumption amount includes:
in the operation of obtaining the output image of the defined quality, predicting cell power consumption based on an average picture level (APL) value and/or a resolution;
in the operation of processing the video signal, predicting video processing power consumption based on the resolution and/or the operation mode;
in the operation for processing the audio signal, predicting audio processing power consumption based on an output volume of the speaker; and
obtaining the resolution or the APL value by analyzing image information about an image being output through the display.

20. The one or more non-transitory computer-readable storage media of claim 19, the operations further comprising:
obtaining the power consumption amount in a power saving operation state; and
in the power saving operation state, obtaining a power saving amount based on an illuminance sensor saving, a motion analysis saving, or an object analysis saving, based on at least one of the PWM, the brightness control value, a dimming block, or a current index according to a dimming scheme for controlling driving of the display.
